(19) United States
(12) Patent Application Publication
(10) Pub. No.: US 2025/0344605 A1
(43) Pub. Date: Nov. 6, 2025

(54) OPTICAL MEMBER DRIVING MECHANISM

(71) Applicant: TDK CORPORATION, Tokyo (JP)

(72) Inventors: Pai-Jui CHENG, Taoyuan City (TW); Shu-Shan CHEN, Taoyuan City (TW); Chuan-Min LEE, Taoyuan City (TW)

(73) Assignee: TDK CORPORATION, Tokyo (JP)

(21) Appl. No.: 19/196,265

(22) Filed: May 1, 2025

Related U.S. Application Data
(60) Provisional application No. 63/642,172, filed on May 3, 2024.

(51) Int. Cl. H10N 30/20; G02B 7/00; H10N 30/88

(52) U.S. Cl. CPC H10N 30/20; G02B 7/00; H10N 30/88

(57) ABSTRACT

An optical member driving mechanism is provided, including a movable portion, a fixed portion, and a driving assembly. The movable portion is configured to connect an optical member, and the movable portion is movable relative to the fixed portion. The driving assembly is configured to drive the movable portion to move.

### CROSS REFERENCE TO RELATED APPLICATIONS

This application claims the benefit of U.S. Provisional Application No. 63/642,172, filed May 3, 2024, the entirety of which is incorporated by reference herein.

### BACKGROUND OF THE INVENTION

### Field of the Invention

The application relates in general to an optical member driving mechanism, and in particular it relates to an optical member driving mechanism for driving the optical member to rotate.

### Description of the Related Art

A lot of optical members require a mechanism that allows them to rotate or move during usage, so as to control their orientation. This mechanism may be a gimbal stabilizer, for example, or a rotating platform. However, the present mechanisms cannot drive an optical member in a power-efficient and stable manner at the same time. Therefore, how to address the aforementioned problem has become an important issue.

### BRIEF SUMMARY OF INVENTION

An embodiment of the invention provides an optical member driving mechanism, including a movable portion, a fixed portion, and a driving assembly. The movable portion is configured to connect an optical member, and is movable relative to the fixed portion. The driving assembly is configured to drive the movable portion to move.

In some embodiments, the driving assembly includes a piezoelectric module, a holding member, and a pressing member. The piezoelectric module is disposed on the fixed portion. The holding member is connected to the piezoelectric module. The pressing member is connected to the holding member and provides a pushing force that is toward the movable portion to the holding member.

In some embodiments, the pressing member includes a sheet spring, and the sheet spring has a first fixing section, a second fixing section, and a string. The first fixing section is connected to the surface of the holding member. The second fixing section is connected to the fixed portion. The string is connected to the first fixing section and the second fixing section. As observed along a direction that is parallel to the surface, at least a portion of the string overlaps the holding member. As observed along a direction that is perpendicular to the surface, the string does not overlap the holding member.

In some embodiments, the second fixing section has a first hole, a second hole, a third hole, and a fourth hole, and the fixed portion has a first protruding pillar, a second protruding pillar, a third protruding pillar, and a fourth protruding pillar. The first protruding pillar, the second protruding pillar, the third protruding pillar, and the fourth protruding pillar respectively pass the first hole, the second hole, the third hole, and the fourth hole. The dimensions of the first hole are substantially the same as the dimensions of the first protruding pillar, the dimensions of the second hole are greater than the dimensions of the second protruding pillar, the dimensions of the third hole are greater than the dimensions of the third protruding pillar, and the dimensions of the fourth hole are greater than the dimensions of the fourth protruding pillar.

In some embodiments, the greatest distance between the second protruding pillar and the inner wall of the second hole is less than the greatest distance between the fourth protruding pillar and the inner wall of the fourth hole, and the greatest distance between the third protruding pillar and the inner wall of the third hole is less than the greatest distance between the fourth protruding pillar and the inner wall of the fourth hole.

In some embodiments, the connection lines of the centers of the first hole, the second hole, the third hole, and the fourth hole form a virtual quadrangle, and the first hole and the fourth hole are disposed on opposite corners of the virtual quadrangle.

In some embodiments, the fourth hole has an oval structure, and a major axis of the oval structure is parallel to the connection line between the centers of the fourth hole and the second hole or the connection line between the centers of the fourth hole and the third hole.

In some embodiments, the first fixing section is disposed in the virtual quadrangle.

In some embodiments, the fixed portion includes a stopping block, the piezoelectric module is disposed between the surface and the stopping block, and the piezoelectric module and the holding member are in contact with the stopping block.

In some embodiments, the second fixing section is connected to the connecting surface of the fixed portion, and in a direction that is perpendicular to the surface, the connecting surface is spaced apart from the surface by a distance.

In some embodiments, the surface is inclined relative the connecting surface.

In some embodiments, as observed along the direction that is parallel to the surface, the string is inclined relative to the surface.

In some embodiments, the pressing member includes a first magnetic member and a second magnetic member. The first magnetic member is disposed on the holding member. The second magnetic member is disposed on the fixed portion and corresponds to the first magnetic member.

In some embodiments, the piezoelectric module includes non-ferromagnetic material.

In some embodiments, the holding member includes a guiding protrusion protruding from a lateral surface of the holding member, the fixed portion includes a guiding recess, and the guiding protrusion is slidably disposed in the guiding recess. The guiding protrusion has a first side and a second side, the second side is connected to a bottom surface of the holding member, an obtuse angle is formed between the second side and the bottom surface, and the first side is connected to the second side.

In some embodiments, a length of the first side is different from a length of the second side.

In some embodiments, a round corner is formed between the first side and the second side, and a gap is formed between the round corner and the inner surface of the guiding recess.

In some embodiments, the pressing member includes a ball, a first recess, and a second recess. The first recess is formed on the holding member. The second recess is formed on the fixed portion. The ball is accommodated in the first recess and the second recess, and the first recess and the second recess are misaligned with each other.

In some embodiments, the driving assembly includes a soft member accommodated in the first recess or the second recess.

In some embodiments, the ball is in contact with the first recess at three or more contact points, and the ball is in contact with the second recess at three or more contact points.

### BRIEF DESCRIPTION OF DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a schematic diagram of an optical member driving mechanism according to an embodiment of the invention;

FIG. 1B is a schematic diagram of the optical member driving mechanism in another view according to an embodiment of the invention;

FIG. 1C is a top view of the optical member driving mechanism according to an embodiment of the invention;

FIG. 1D is a side view of the optical member driving mechanism according to an embodiment of the invention;

FIG. 1E is a schematic diagram of a piezoelectric module in the optical member driving mechanism according to an embodiment of the invention;

FIG. 2A is a schematic diagram of an optical member driving mechanism according to another embodiment of the invention;

FIG. 2B is a cross-sectional view taken along the line A-A in FIG. 2A;

FIG. 2C is a cross-sectional view taken along the line B-B in FIG. 2A;

FIG. 2D is a schematic diagram of an optical member driving mechanism according to another embodiment of the invention;

FIG. 3A is a schematic diagram of an optical member driving mechanism according to another embodiment of the invention;

FIG. 3B is a partial enlarged diagram of the optical member driving mechanism according to another embodiment of the invention; and

FIG. 3C is a cross-sectional view taken along the line C-C in FIG. 3A.

### DETAILED DESCRIPTION OF INVENTION

The making and using of the embodiments of the optical member driving mechanism are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

The following disclosure provides many different embodiments, or examples, for implementing different features of the subject matter provided. Specific examples of solutions and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

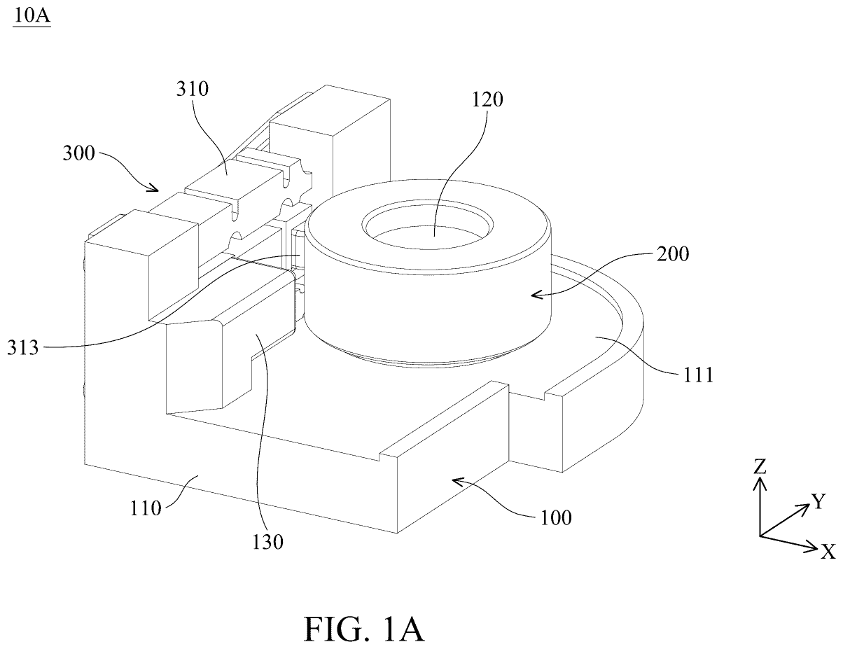

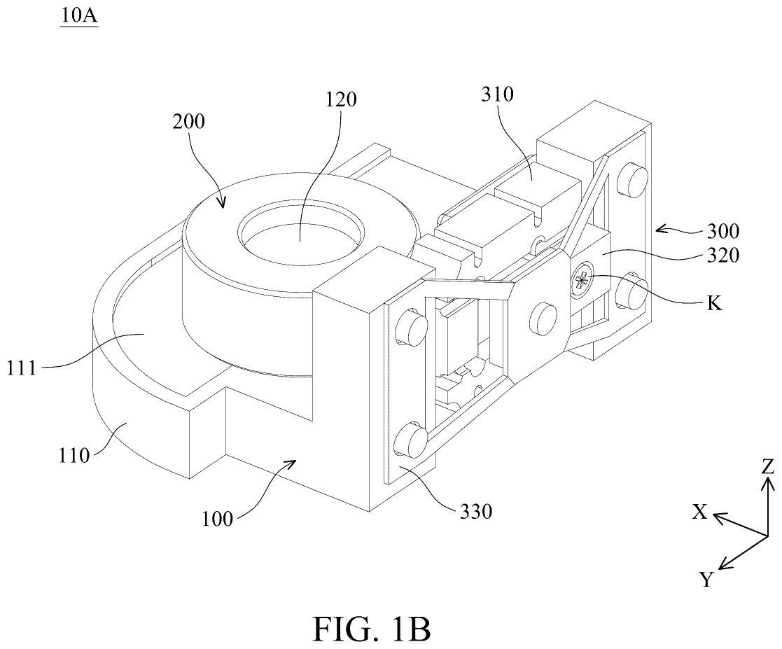

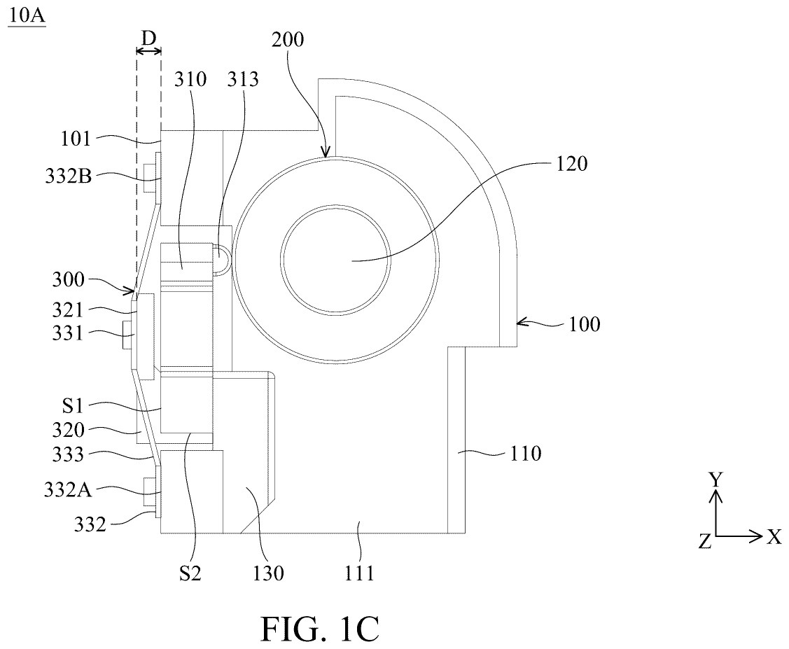

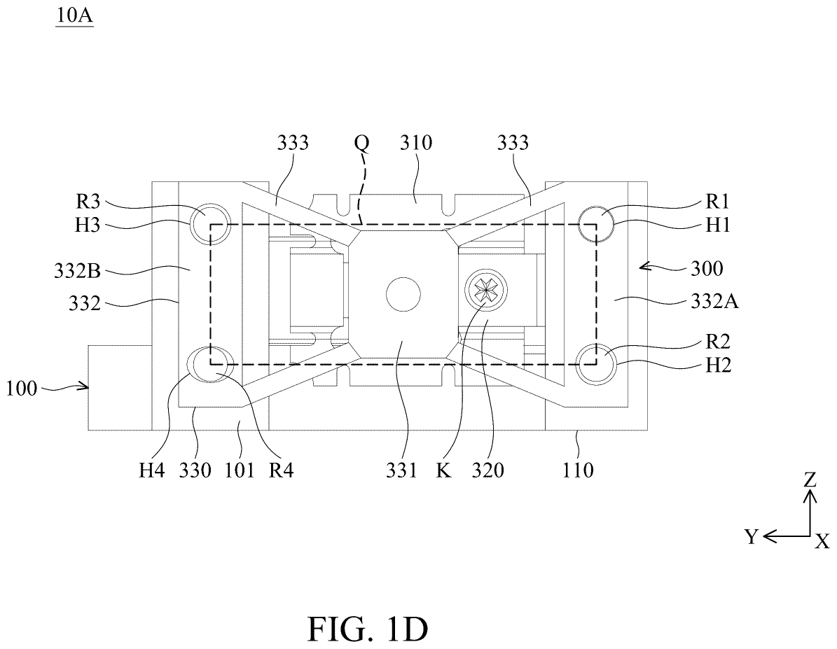

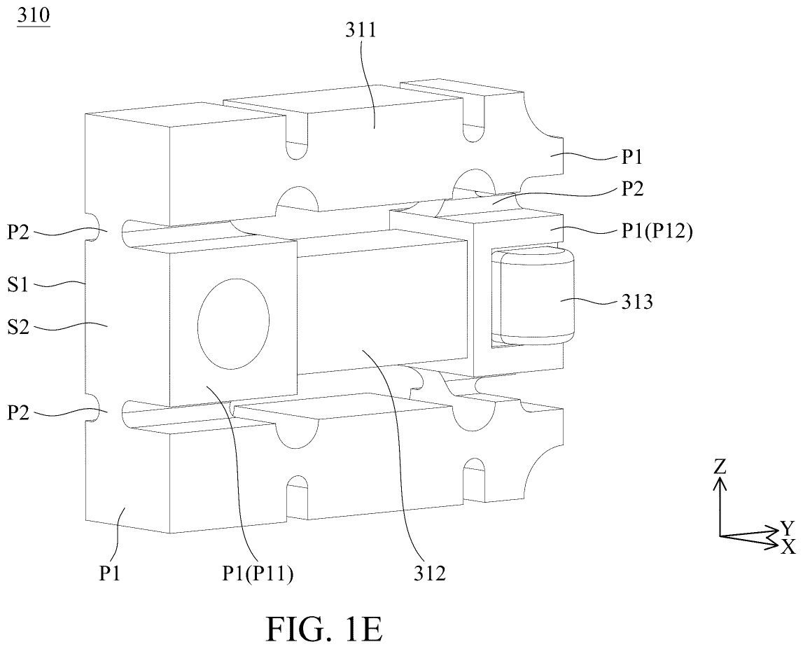

Referring to FIG. 1A to FIG. 1D, an optical member driving mechanism 10A according to an embodiment of the invention primarily includes a fixed portion 100, a movable portion 200, and a driving assembly 300. The fixed portion 100 includes a base 110 and a shaft 120. The shaft 120 is connected to the base 110 and protrudes from an upper surface 111 of the base 110. The movable portion 200 has an annular structure. The movable portion 120 is disposed on the upper surface 111 of the base 110 and surrounds the shaft 120. The driving assembly 300 is disposed on the base 110 and situated at a side of the movable portion 200. The driving assembly 300 can provide a driving force to the movable portion 200 to rotate the movable portion 200 around the shaft 120. The external optical member (not shown) can be connected to the movable portion 200. When the driving assembly 300 drives the movable portion 200 to rotate, the optical member can rotate accordingly

For example, the optical can include a photographing member (such as a camera), an image sensor, a detecting member (such as an infrared detector), and/or a display member (such as a monitor), but it is not limited thereto.

The driving assembly 300 includes a piezoelectric module 310, a holding member 320, and a pressing member 330. As shown in FIG. 1E, the piezoelectric module 310 includes a deforming member 311, a piezoelectric member 312, and a contacting member 313. The deforming member 311 includes a flexible material, and includes a plurality of primary parts Pl and a plurality of secondary parts P2. The primary parts P1 surround the piezoelectric member 312. The secondary parts P2 connect the primary parts P1. In a direction that is parallel to the rotation axis of the movable portion 200, the thickness of each of the secondary parts P2 is less than the thickness of each of the primary part P1.

The opposite ends of the piezoelectric member 312 are respectively connected to two primary parts P11 and P12 on the opposite sides of the piezoelectric module 310, and the contacting member 313 is disposed on the primary part P12 which is one of the primary parts P1 connected by the piezoelectric member 312. When the driving assembly 300 is disposed on the fixed portion 100, the contacting member 313 is in contact with the movable portion 200. Once the current flows into the piezoelectric member 312, the length of the piezoelectric member 312 changes, and the deforming member 311 is deformed accordingly. Therefore, the contacting member 313 on the deforming member 313 can move to roll the movable portion 200, and the movable portion 200 can rotate relative to the fixed portion 100.

Referring to FIG. 1A to FIG. 1D, the piezoelectric module 310 is connected to the holding member 320, and the piezoelectric module 310 can be affixed to the fixed portion 100 via the holding member 320. In detail, the holding member 320 has a L-shaped structure, and can be in contact with two adjacent surfaces S1 and S2 of the primary part P11 which is connected to the piezoelectric member 312. The fixed portion 100 includes a stopping block 130 protruding from the upper surface 111 of the base 110. A locking member K (such as a screw) can pass through the holding member 320 and the primary part P11 of the deforming member 311 and engage the stopping block 130. Thus, the holding member 320 and the piezoelectric member 312 can be affixed to the fixed portion 100. In this embodiment, since the holding member 320 has the L-shaped structure, both the holding member 320 and the piezoelectric module 310 can be in contact with the stopping block 130.

In some embodiments, the locking member K can be omitted, and the holding member 320 and the piezoelectric module 310 can abut against the stopping block 130 by the pushing force provided from the pressing member 330.

The pressing member 330 is configured to ensure that the contacting member 313 of the piezoelectric module 310 is in contact with the movable portion 200. In this embodiment, the pressing member 330 includes a sheet spring having a first fixing section 331, a second fixing section 332, and a plurality of strings 333. The first fixing section 331 is affixed to the surface 321 of the holding member 320, the second fixing section 332 is affixed to the connecting surface 101 of the fixed portion 100, and the strings 333 are connected to the first fixing section 331 and the second fixing section 332. The surface 321 of the holding member 320 faces away the piezoelectric module 310, and the connecting surface 101 and the surface 321 face the same direction.

In this embodiment, the second fixing section 332 has two separated units 332A and 332B, and the first fixing section 331 is disposed between the aforementioned units 332A and 332B. The unit 332A of the second fixing section 332 has a first hole H1 and a second hole H2, and the unit 332B of the second fixing section 332 has a third hole H3 and a fourth hole H4. The centers of the first hole H1, the second hole H2, the third hole H3, and the fourth hole H4 can form a virtual quadrangle Q. The first hole Hl and the fourth hole H4 are disposed on the opposite corners of the virtual quadrangle Q, the second hole H2 and the third hole H3 are disposed on the opposite corners of the virtual quadrangle Q, and the first fixing section 331 is disposed in the virtual quadrangle Q.

The fixed portion 100 includes a first protruding pillar R1, a second protruding pillar R2, a third protruding pillar R3, and a fourth protruding pillar R4 respectively passing the first hole H1, the second hole H2, the third hole H3, and the fourth hole H4 on the second fixing section 332. Specifically, the dimensions of the first hole H1 are substantially the same as that of the first protruding pillar R1, the dimensions of the second hole H2 is greater than that of the second protruding pillar R2, the dimensions of the third hole H3 is greater than that of the third protruding pillar R3, and the dimensions of the fourth hole H4 is greater than that of the fourth protruding pillar R4. In this embodiment, the dimensions of the first protruding pillar R1, the second protruding pillar R2, the third protruding pillar R3, and the fourth protruding pillar R4 are substantially the same.

The greatest distance between the fourth protruding pillar R4 and the inner wall of the fourth hole H4 is greater than the greatest distance between the second protruding pillar R2 and the inner wall of the second hole H2, and is also greater than the greatest distance between the third protruding pillar R3 and the inner wall of the third hole H3. In this embodiment, the fourth hole H4 has an oval structure, and the major axis of the oval structure is parallel to the connection line between the centers of the second protruding pillar R2 and the fourth protruding pillar R4. In some embodiments, the major axis of the oval structure is parallel to the connection line between the centers of the third protruding pillar R3 and the fourth protruding pillar R4.

Owing to the arrangement of the first hole H1, the second hole H2, the third hole H3, and the fourth hole H4, the pressing member 330 is facilitated to assemble, and the manufacturing speed and the yield of the optical member driving mechanism 10A can be enhanced.

As shown in FIG. 1C, in a direction that is perpendicular to the surface 321 of the holding member 320, a distance D is formed between the connecting surface 101 of the fixed portion 100 and the surface 321 of the holding member 320. Therefore, the pressing member 330 can continuously provide a pushing force to the piezoelectric module 310 by the elastic force of the pressing member 330, and the contacting member 313 of the piezoelectric module 310 and the movable portion 200 can be kept in contact. Moreover, since the piezoelectric module 310 receives the pushing force of the pressing member 330, the surface 321 of the holding member 320 may be inclined relative to the connecting surface 101 of the fixed portion 100.

Furthermore, as shown in FIG. 1C and FIG. 1D, in this embodiment, as observed along a direction that is parallel to the surface 321 of the holding member 320, the piezoelectric module 310 is disposed between the surface 321 of the holding member 320 and the stopping block 130, the strings 333 are inclined relative to the surface 321 of the holding member 320, and at least a portion of the strings 333 overlaps the holding member 320. As observed along a direction that is perpendicular to the surface 321 of the holding member 320, the strings 333 do not overlap the holding member 320. Therefore, the optical member driving mechanism 10A can be efficiently miniaturized.

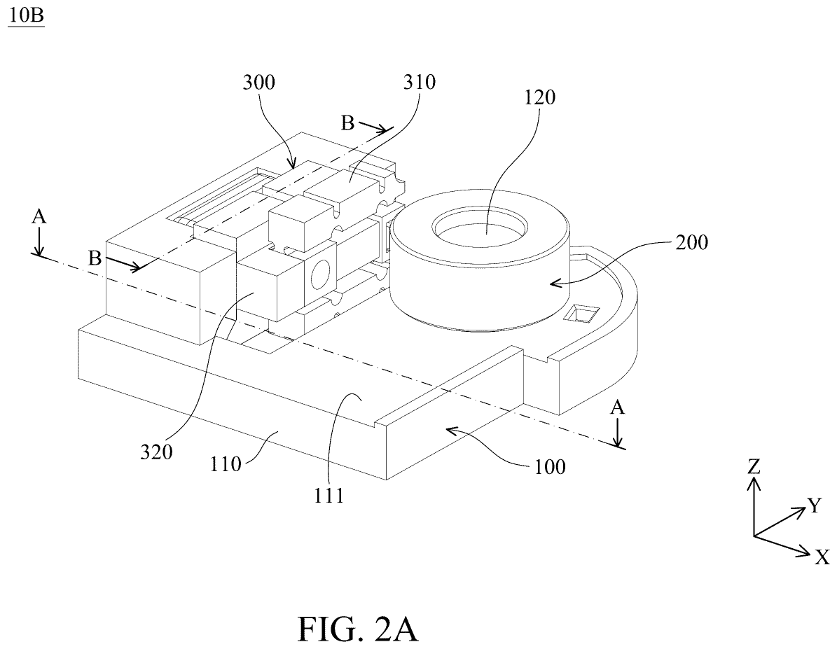

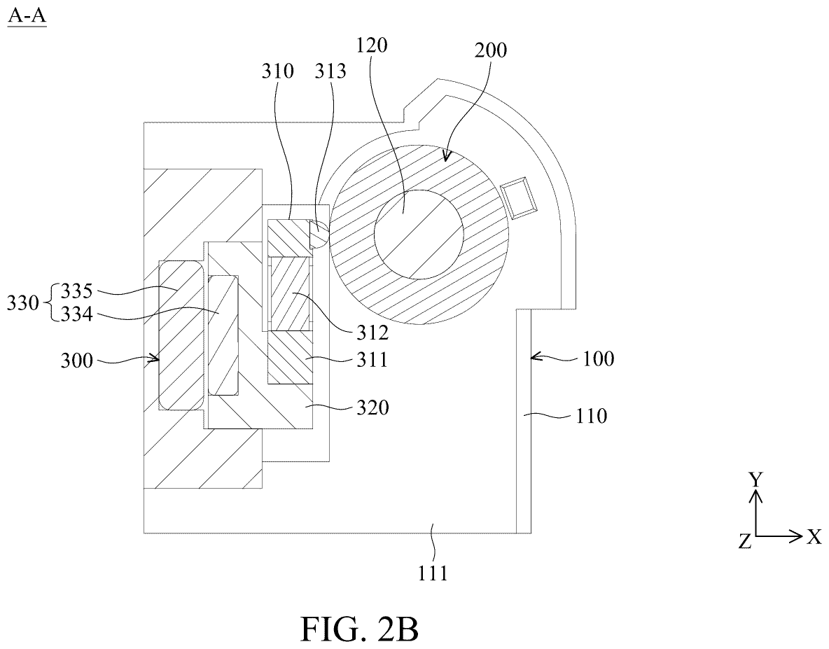

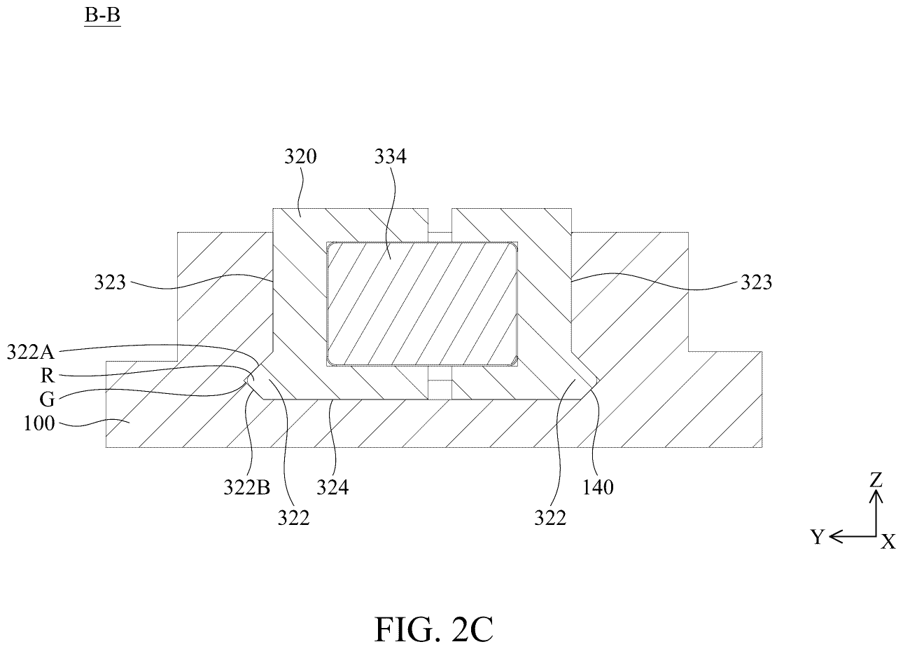

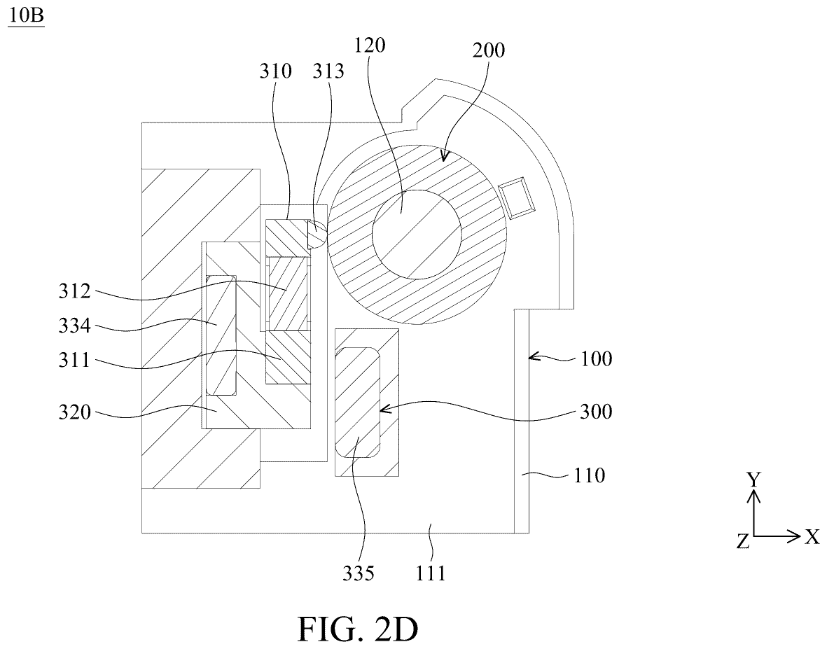

FIG. 2A is a schematic diagram of an optical member driving mechanism 10B according to another embodiment of the invention, FIG. 2B is a cross-sectional view taken along the line A-A in FIG. 2A, and FIG. 2C is a cross-sectional view taken along the line B-B in FIG. 2A. As shown in FIG. 2A to FIG. 2C, the optical member driving mechanism 10B primarily includes a fixed portion 100, a movable portion 200, and a driving assembly 300. The fixed portion 100 includes a base 110 and a shaft 120. The shaft 120 is connected to the base 110 and protrudes from an upper surface 111 of the base 110. The movable portion 200 has an annular structure. The movable portion 120 is disposed on the upper surface 111 of the base 110 and surrounds the shaft 120. The driving assembly 300 is disposed on the base 110 and situated at a side of the movable portion 200. The driving assembly 300 can provide a driving force to the movable portion 200 to rotate the movable portion 200 around the shaft 120. The external optical member (not shown) can be connected to the movable portion 200. When the driving assembly 300 drives the movable portion 200 to rotate, the optical member can rotate accordingly.

The driving assembly 300 includes a piezoelectric module 310, a holding member 320, and a pressing member 330. The piezoelectric module 310 and the holding member 320 are similar to the embodiment shown in FIG. 1A to FIG. 1D, so that the features thereof are not repeated in the interest of brevity.

In this embodiment, the pressing member 330 includes a first magnetic member 334 and a second magnetic member 335. The first magnetic member 334 is disposed on the holding member 320, the second magnetic member 335 is disposed on the fixed portion 100, and the first magnetic member 334 corresponds to the second magnetic member 335.

Since the first magnetic member 334 is disposed between the second magnetic member 335 and the movable portion 200, and a magnetic repulsion force is generated between the first magnetic member 334 and the second magnetic member 335, the pressing member 330 can continuously provide a pushing force to the piezoelectric module 310 by the aforementioned magnetic repulsion force, and the contacting member 313 of the piezoelectric module 310 and the movable portion 200 can be kept in contact.

In this embodiment, the piezoelectric module 310 includes non-ferromagnetic material, so that the piezoelectric module 310 can be prevented from being attracted by the first magnetic member 334 or the second magnetic member 335 and moving toward a direction away from the movable portion 200.

Referring to FIG. 2C, in this embodiment, the holding member 320 includes one or more guiding protrusions 322. The protrusion 322 protrude from the lateral surface 323 of the holding member 320 and connects to the bottom surface 324 of the holding surface 320. The fixed portion 100 has one or more guiding recesses 140 corresponding to the guiding protrusion 322. The dimensions of the guiding recess 140 are substantially the same as that of the guiding protrusion 322, and the guiding protrusion 322 is slidably accommodated in the guiding recess 140.

It should be noted that, the guising protrusion 322 has a first side 322A and a second side 322B. The second side 322B is connected to the bottom surface 324 of the holding member 320, and an obtuse angle is formed between the second side 322B and the bottom surface 324 of the holding member 320. The first side 322A is connected to the second side 322B, and the length of the first side 322A is greater than the length of the second side 322B. Owing the guiding protrusion 322 and the guiding recess 140, the piezoelectric module 310 can be prevented from tilting due to the pushing force of the pressing member 330.

In this embodiment, a round corner R is formed between the first side 322A and the second side 322B. A gap G is formed between the round corner R and the inner wall of the guiding recess 140, and the lubricant can be filled into the gap G to reduce the friction between the holding member 320 and the fixed portion 100.

Referring to FIG. 2D, in another embodiment of the invention, the piezoelectric module 310 can be disposed between the first magnetic member 334 and the second magnetic member 335, and a magnetic attraction force can be generated between the first magnetic member 334 and the second magnetic member 335. Therefore, in this embodiment, the piezoelectric module 310 can still abut toward the movable portion 200, and the contacting member 313 of the piezoelectric module 310 and the movable portion 200 can be kept in contact.

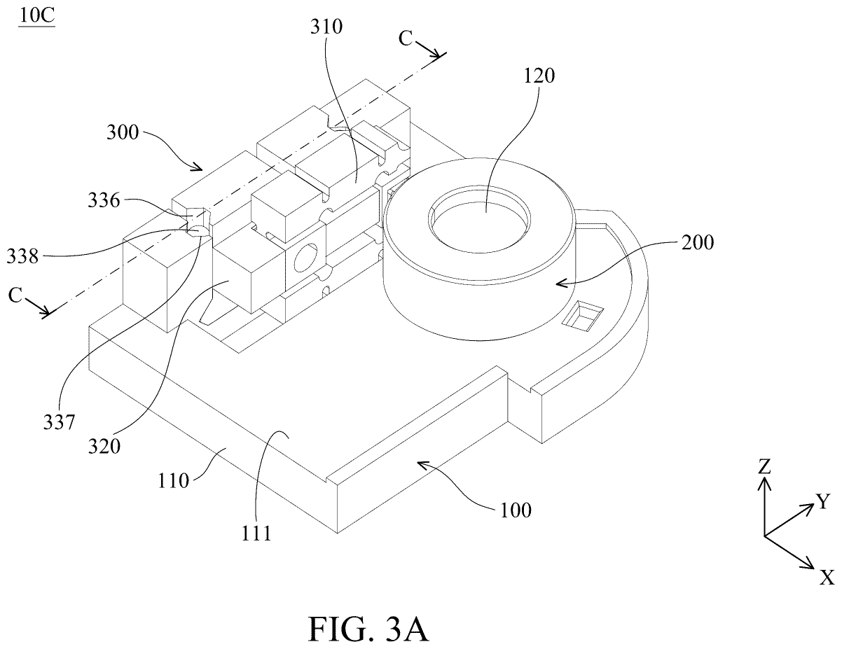

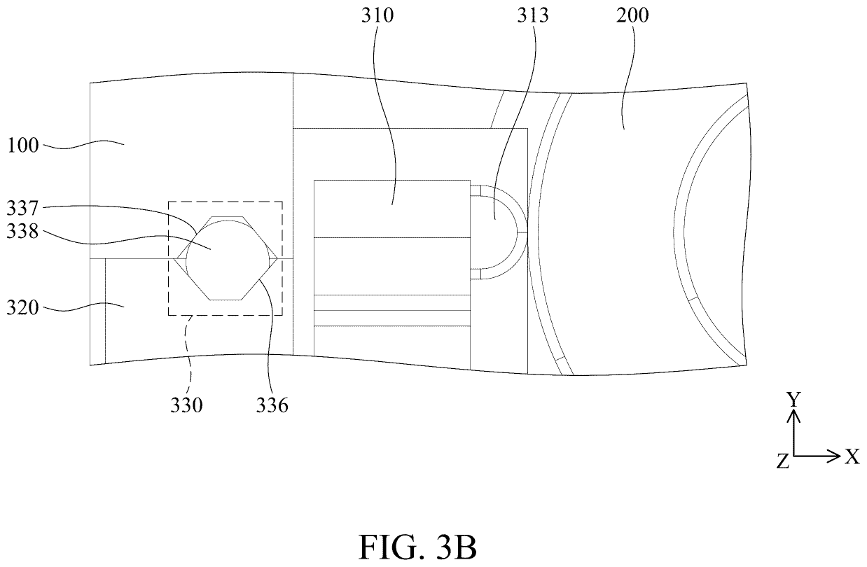

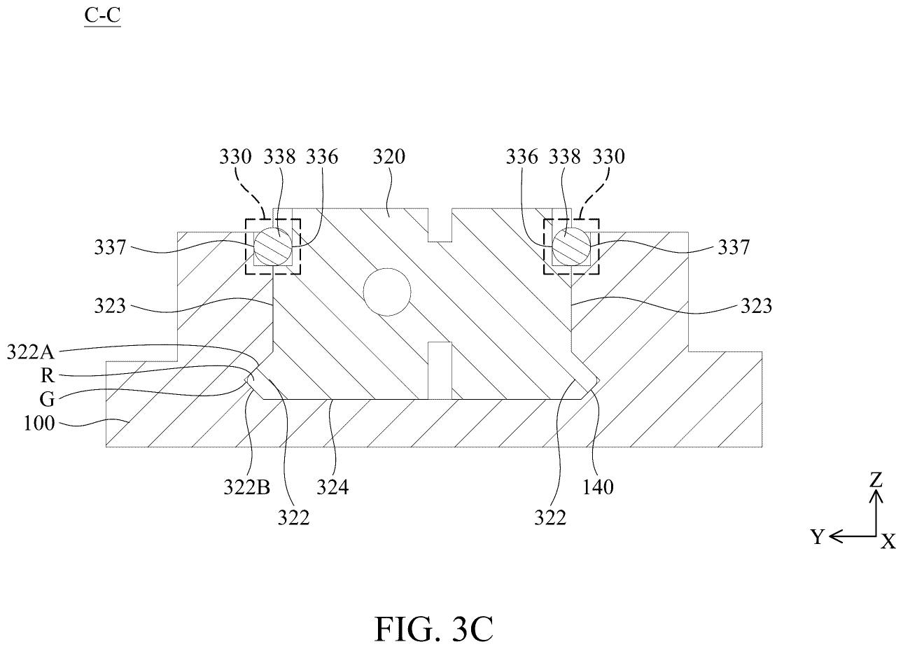

FIG. 3A is a schematic diagram of an optical member driving mechanism 10C according to another embodiment of the invention, FIG. 3B is a partial enlarged diagram of the optical member driving mechanism 10C, and FIG. 3C is a cross-sectional view taken along the line C-C in FIG. 3A. As shown in FIG. 3A to FIG. 3C, the optical member driving mechanism 10C primarily includes a fixed portion 100, a movable portion 200, and a driving assembly 300. The fixed portion 100 includes a base 110 and a shaft 120. The shaft 120 is connected to the base 110 and protrudes from an upper surface 111 of the base 110. The movable portion 200 has an annular structure. The movable portion 120 is disposed on the upper surface 111 of the base 110 and surrounds the shaft 120. The driving assembly 300 is disposed on the base 110 and situated at a side of the movable portion 200. The driving assembly 300 can provide a driving force to the movable portion 200 to rotate the movable portion 200 around the shaft 120. The external optical member (not shown) can be connected to the movable portion 200. When the driving assembly 300 drives the movable portion 200 to rotate, the optical member can rotate accordingly.

The driving assembly 300 includes a piezoelectric module 310, a holding member 320, and a pressing member 330. The piezoelectric module 310 and the holding member 320 are similar to the embodiment shown in FIG. 1A to FIG. 1D, so that the features thereof are not repeated in the interest of brevity.

In this embodiment, the pressing member 330 includes at least one first recess 336, at least one second recess 337, and at least one ball 338. The first recess 336 is formed on the holding member 320, the second recess is formed on the fixed portion 100, and the ball 338 is accommodated in the first recess 336 and the second recess 337.

The ball 338 is in contact with the first recess 336 at three or more contact points, the ball 338 is in contact with the second recess 337 at three or more contact points, and the first recess 336 and the second recess 337 are misaligned with each other (that is, the first recess 336 and the second recess 337 can include the same shape and the same dimensions, however, when the holding member 320 is assembled to the fixed portion 100 and the ball 338 is not put in, the first recess 336 and the second recess 337 are not aligned with each other). Therefore, when the ball 338 enters the first recess 336 and the second recess 337, the ball 338 can force the first recess 336 to be aligned with the second recess 337. The holding member 320 can receiver a pushing force toward the movable portion 200, and the contacting member 313 of the piezoelectric module 310 and the movable portion 200 can be kept in contact. Moreover, the driving assembly 300 can include a soft member (not shown) accommodated in the first recess 336 or the second recess 337.

As shown in FIG. 3C, in this embodiment, the holding member 320 has one or more guiding protrusions 322, and the fixed portion 100 has one or more guiding recesses 140 corresponding to the guiding protrusions 322. The guiding protrusion 322 and the guiding recess 140 are the same as the embodiment shown in FIG. 2C, so that the features thereof are not repeated in the interest of brevity.

The features between the aforementioned embodiments can be used or combined as long as they do not violate the spirit or conflict.

In summary, an embodiment of the invention provides an optical member driving mechanism, including a movable portion, a fixed portion, and a driving assembly. The movable portion is configured to connect an optical member, and is movable relative to the fixed portion. The driving assembly is configured to drive the movable portion to move.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An optical member driving mechanism, comprising:
a movable portion, configured to connect an optical member;
a fixed portion, wherein the movable portion is movable relative to the fixed portion; and
a driving assembly, configured to drive the movable portion to move.

2. The optical member driving mechanism as claimed in claim 1, wherein the driving assembly comprises:
a piezoelectric module, disposed on the fixed portion;
a holding member, connected to the piezoelectric module; and
a pressing member, connected to the holding member, providing a pushing force on the holding member, and pushing the holding member toward the movable portion.

3. The optical member driving mechanism as claimed in claim 2, wherein the pressing member comprises a sheet spring, and the sheet spring comprises:
a first fixing section, connected to a surface of the holding member;
a second fixing section, connected to the fixed portion; and
a string, connected to the first fixing section and the second fixing section, wherein as observed along a direction that is parallel to the surface, at least a portion of the string overlaps the holding member, wherein as observed along a direction that is perpendicular to the surface, the string does not overlap the holding member.

4. The optical member driving mechanism as claimed in claim 3, wherein the second fixing section has a first hole, a second hole, a third hole, and a fourth hole, the fixed portion has a first protruding pillar, a second protruding pillar, a third protruding pillar, and a fourth protruding pillar, and the first protruding pillar, the second protruding pillar, the third protruding pillar, and the fourth protruding pillar respectively pass the first hole, the second hole, the third hole, and the fourth hole, wherein the dimensions of the first hole are substantially the same as the dimensions of the first protruding pillar, the dimensions of the second hole are greater than the dimensions of the second protruding pillar, the dimensions of the third hole are greater than the dimensions of the third protruding pillar, and the dimensions of the fourth hole are greater than the dimensions of the fourth protruding pillar.

5. The optical member driving mechanism as claimed in claim 4, wherein a greatest distance between the second protruding pillar and an inner wall of the second hole is less than a greatest distance between the fourth protruding pillar and an inner wall of the fourth hole, and a greatest distance between the third protruding pillar and an inner wall of the third hole is less than the greatest distance between the fourth protruding pillar and the inner wall of the fourth hole.

6. The optical member driving mechanism as claimed in claim 5, wherein connection lines of centers of the first hole, the second hole, the third hole, and the fourth hole form a virtual quadrangle, and the first hole and the fourth hole are disposed on opposite corners of the virtual quadrangle.

7. The optical member driving mechanism as claimed in claim 6, wherein the fourth hole has an oval structure, and a major axis of the oval structure is parallel to the connection line between the centers of the fourth hole and the second hole or the connection line between the centers of the fourth hole and the third hole.

8. The optical member driving mechanism as claimed in claim 6, wherein the first fixing section is disposed in the virtual quadrangle.

9. The optical member driving mechanism as claimed in claim 3, wherein the fixed portion comprises a stopping block, the piezoelectric module is disposed between the surface and the stopping block, and the piezoelectric module and the holding member are in contact with the stopping block.

10. The optical member driving mechanism as claimed in claim 3, wherein the second fixing section is connected to the connecting surface of the fixed portion, and in a direction that is perpendicular to the surface, the connecting surface is spaced apart from the surface by a distance.

11. The optical member driving mechanism as claimed in claim 10, wherein the surface is inclined relative to the connecting surface.

12. The optical member driving mechanism as claimed in claim 3, wherein as observed along the direction that is parallel to the surface, the string is inclined relative to the surface.

13. The optical member driving mechanism as claimed in claim 2, wherein the pressing member comprises:
a first magnetic member, disposed on the holding member; and
a second magnetic member, disposed on the fixed portion and corresponding to the first magnetic member.

14. The optical member driving mechanism as claimed in claim 13, wherein the piezoelectric module comprises non-ferromagnetic material.

15. The optical member driving mechanism as claimed in claim 2, wherein the holding member comprises a guiding protrusion protruding from a lateral surface of the holding member, the fixed portion comprises a guiding recess, and the guiding protrusion is slidably disposed in the guiding recess, wherein the guiding protrusion has a first side and a second side, the second side is connected to a bottom surface of the holding member, an obtuse angle is formed between the second side and the bottom surface, and the first side is connected to the second side.

16. The optical member driving mechanism as claimed in claim 15, wherein a length of the first side is different from a length of the second side.

17. The optical member driving mechanism as claimed in claim 15, wherein a round corner is formed between the first side and the second side, and a gap is formed between the round corner and an inner surface of the guiding recess.

18. The optical member driving mechanism as claimed in claim 2, wherein the pressing member comprises:
a ball;
a first recess, formed on the holding member; and
a second recess, formed on the fixed portion, wherein the ball is accommodated in the first recess and the second recess, and the first recess and the second recess are misaligned with each other.

19. The optical member driving mechanism as claimed in claim 18, wherein the driving assembly comprises a soft member accommodated in the first recess or the second recess.

20. The optical member driving mechanism as claimed in claim 18, wherein the ball is in contact with the first recess at three or more contact points, and the ball is in contact with the second recess at three or more contact points.
